(19) United States
(12) Patent Application Publication
(10) Pub. No.: US 2016/0300660 A1
(43) Pub. Date: Oct. 13, 2016

(54) ELECTRONIC DEVICE

(71) Applicant: Siliconware Precision Industries Co., Ltd., Taichung (TW)

(72) Inventors: Chih-Hsien Chiu, Taichung (TW); Chi-Pin Tsai, Taichung (TW); Ming-Fan Tsai, Taichung (TW); Jyun-Yuan Jhang, Taichung (TW); Chi-Liang Shih, Taichung (TW)

(21) Appl. No.: 14/718,126

(22) Filed: May 21, 2015

(30) Foreign Application Priority Data
Apr. 7, 2015 (TW) 104111081

(51) Int. Cl. H01F 27/28; H01F 27/02

(52) U.S. Cl. CPC H01F 27/2804; H01F 27/022; H01F 2027/2809

(57) ABSTRACT

An electronic device is provided, which includes: a magnetically conductive element having at least a through hole; a conductor structure formed on the magnetically conductive element and in the through hole; and a base body encapsulating the magnetically conductive element and the conductor structure, thereby allowing the electronic device to generate a higher magnetic flux and thus cause an increase in inductance.

### BACKGROUND OF THE INVENTION

1. Field of the Invention

The present invention relates to electronic devices, and more particularly, to an electronic device having a magnetically conductive element.

2. Description of Related Art

Along with the rapid development of electronic industries, electronic products are developed toward the trend of multi-function and high performance. To meet the miniaturization requirement of semiconductor packages, packaging substrates for carrying chips are becoming thinner. Further, the chips are required to have high-integration electronic circuits and high-density I/O connections to increase memory capacities and operating frequencies and reduce voltage requirements, thereby allowing the electronic products to become lighter, thinner, shorter, smaller and faster.

In semiconductor application devices such as communication or high-frequency semiconductor devices, most RF passive elements such as resistors, inductors, capacitors and oscillators are electrically connected to semiconductor chips so as to cause the semiconductor chips to have certain current characteristics or send signals

For example, in a BGA (Ball Grid Array) semiconductor device, most passive elements are mounted on a surface of a substrate. However, to prevent the passive elements from adversely affecting the electrical connection and configuration between semiconductor chips and bonding pads of the substrate, the passive elements are generally mounted at corners of the substrate or a region outside the chip mounting region.

Such a limitation on the position of the passive elements reduces the routing flexibility. Further, the position of the bonding pads limits the number of the passive elements mountable on the substrate, thereby hindering high integration of the semiconductor device. Furthermore, as the high-performance requirement of the semiconductor package causes a great increase in the number of the passive elements, the surface area of the substrate must be increased to accommodate both the semiconductor chips and the passive elements. As such, the semiconductor package is increased in volume and cannot meet the miniaturization requirement.

To overcome the above-described drawbacks, most passive elements are fabricated as lumped elements, for example, chip-type inductors, and integrated at regions between the semiconductor chips and the bonding pads. FIG. 1 is a schematic cross-sectional view of a conventional semiconductor package 1. Referring to FIG. 1, a substrate 10 is provided and a circuit layer 11 having a plurality of bonding pads 110 is formed on the substrate 10. A plurality of inductor elements 12 and a semiconductor chip 13 are mounted on the substrate 10, and the semiconductor chip 13 is electrically connected to the bonding pads 110 through a plurality of bonding wires 130.

However, as the number of I/O connections per unit area of the semiconductor device increases, the number of the bonding wires 130 increases. Generally, the height of the inductor elements 12 (0.8 mm) is greater than the height of the semiconductor chip 13 (0.55 mm) As such, the bonding wires 130 easily come into contact with the inductor elements 12, thereby causing a short circuit to occur.

To overcome the drawback of short circuit, the wire loop of the bonding wires 130 needs to be pulled up and positioned over the inductor elements 12. But such a method increases the bonding difficulty and complicates the fabrication process. Also, since the length of the wire loop of the bonding wires 130 is increased, the fabrication cost of the bonding wires 130 is increased significantly. In addition, if the bonding wires 130 lack an effective support, the bonding wires 130 easily sag under gravity and come into contact with the inductor elements 12, thus causing a short circuit to occur.

Further, the inductor elements 12, especially those in power supply circuits, are chip-type and have a large volume. In addition, the parasitic effect increase as the distance between the inductor elements 12 and the semiconductor chip 13 increases.

Referring to FIG. 1′, the inductor elements 12 are replaced with coil-type inductors 12′ to overcome the above-described drawbacks. However, since the coil-type inductors 12′ are only mounted on the substrate 10, the simulated inductance value of the inductors 12′ is 17 Nh (on an area of 2.0 mm×1.25 mm) As such, the inductance value of the coil-type inductors 12′ is too small to meet the requirement.

Therefore, how to overcome the above-described drawbacks has become critical.

### SUMMARY OF THE INVENTION

In view of the above-described drawbacks, the present invention provides an electronic device, which comprises: a magnetically conductive element having a first surface, a second surface opposite to the first surface, an outer side surface adjacent to and connecting the first surface and the second surface, and at least a through hole communicating the first surface and the second surface; a conductor structure formed on the first surface, the second surface and the outer side surface of the magnetically conductive element and extending into the through hole for generating a magnetic flux; and a base body encapsulating the magnetically conductive element and the conductor structure.

In the above-described electronic device, the base body can comprise a substrate and an encapsulant, wherein the magnetically conductive element and the conductor structure are positioned on the substrate and encapsulated by the encapsulant.

In the above-described electronic device, the magnetically conductive element can be made of ferrite, Fe, Mn, Zn, Ni or an alloy thereof.

In the above-described electronic device, the conductor structure can comprise a circuit layer formed on the first surface of the magnetically conductive element and a plurality of conductive wires formed over the second surface of the magnetically conductive element, wherein each of the conductive wires has two opposite ends electrically connected to the circuit layer. In an embodiment, the circuit layer has a plurality of conductive traces, and the two opposite ends of each of the conductive wires are electrically connected to different two of the conductive traces, respectively.

In the above-described electronic device, the conductor structure can further comprise a plurality of bonding pads formed on the second surface of the magnetically conductive element, and each of the conductive wires can have two segments bonded to a corresponding one of the bonding pads, wherein one of the segments extends in the through hole of the magnetically conductive element for connecting the circuit layer and the bonding pad and the other segment extends over the outer side surface of the magnetically conductive element for connecting the circuit layer and the bonding pad.

In an embodiment, the conductor structure further comprises a plurality of conductive posts formed on the circuit layer in the through hole of the magnetically conductive element, wherein one ends of the conductive wires are bonded to the conductive posts.

In an embodiment, the conductor structure further comprises a plurality of conductive posts formed on the circuit layer at an outer periphery of the outer side surface of the magnetically conductive element, wherein one ends of the conductive wires are bonded to the conductive posts. Furthermore, a plurality of conductive posts can be formed on the circuit layer in the through hole of the magnetically conductive element, and the other ends of the conductive wires are bonded to the conductive posts in the through hole.

In the above-described electronic device, the through hole can be a closed through hole or an open through hole. The open through hole can have at least an opening.

According to the present invention, the conductor structure is formed around the magnetically conductive element having a through hole so as to generate a magnetic flux and thus cause an increase in inductance.

Further, since the magnetically conductive element facilitates to increase the inductance value of a single coil, the present invention can achieve the same inductance value as the prior art by using a reduced number of coils. Therefore, the volume of the inductor is minimized.

### BRIEF DESCRIPTION OF DRAWINGS

FIGS. 1 and 1′ are schematic cross-sectional views of conventional semiconductor packages;

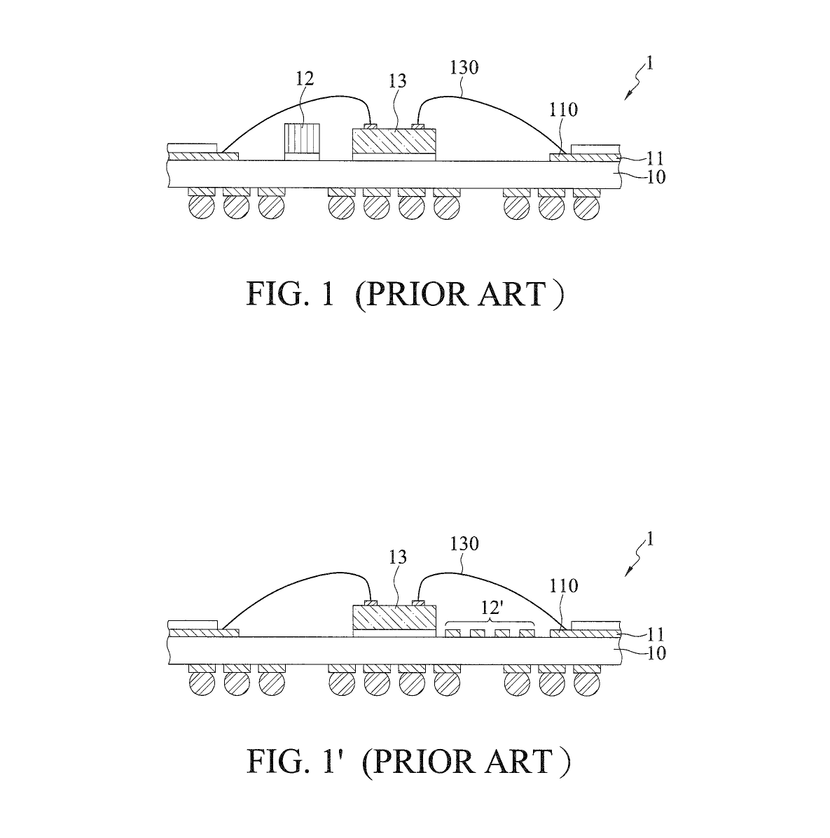

FIG. 2 is a schematic cross-sectional view of an electronic device according to a first embodiment of the present invention;

FIG. 2′ is a schematic partial perspective view of the electronic device of FIG. 2;

FIG. 3 is a schematic cross-sectional view of an electronic device according to a second embodiment of the present invention;

FIGS. 4A to 4C are schematic cross-sectional views of electronic devices according to a third embodiment of the present invention;

FIG. 5 is a schematic upper view of an electronic device according to a fourth embodiment of the present invention; and

FIGS. 6A to 6G are schematic upper views of electronic devices according to a fifth embodiment of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

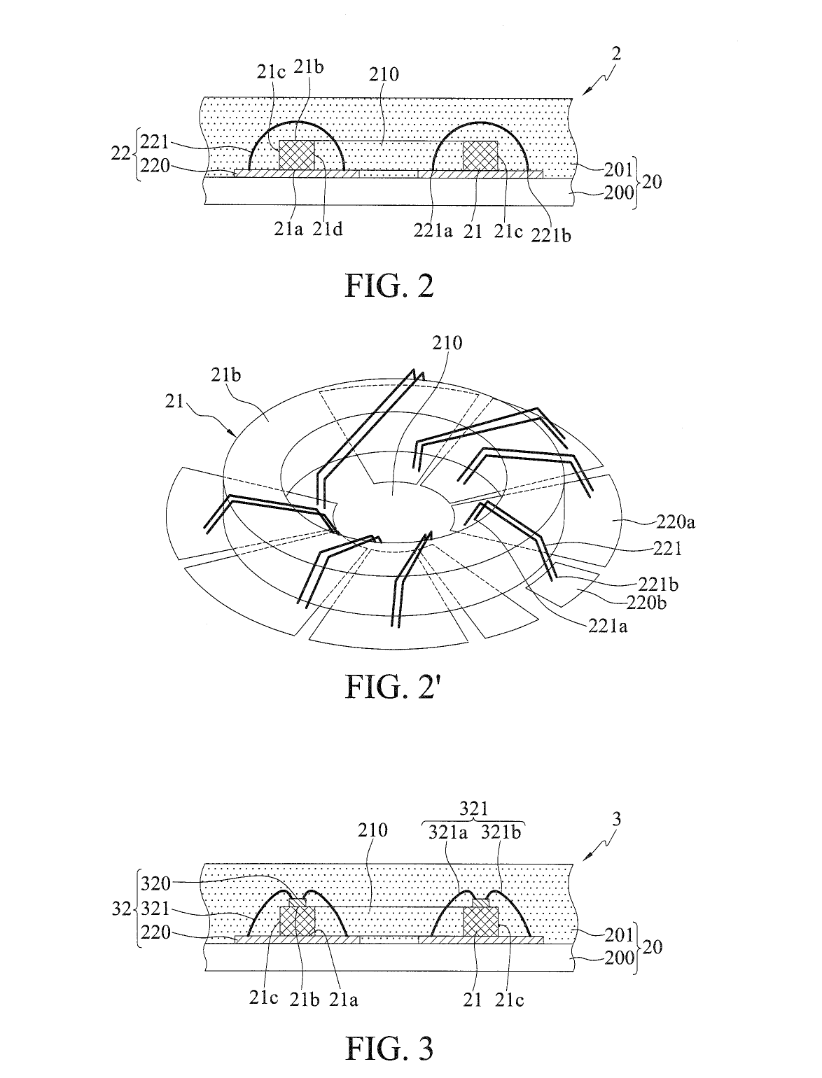

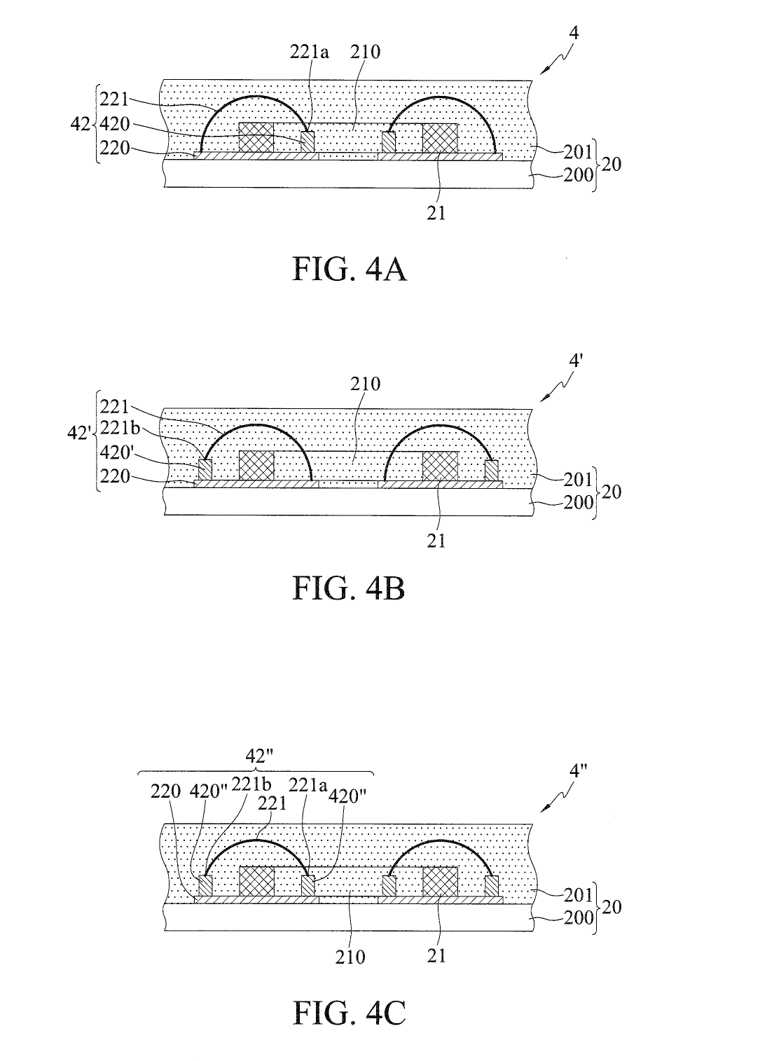

FIGS. 2 and 2′ show an electronic device 2 according to a first embodiment of the present invention.

Referring to FIGS. 2 and 2′, the electronic device 2 has a magnetically conductive element 21, a conductor structure 22 formed around the magnetically conductive element 21, and a base body 20 encapsulating the magnetically conductive element 21 and the conductor structure 22.

The magnetically conductive element 21 has high permeability and is made of ferrite, Fe, Mn, Zn, Ni or an alloy thereof. The magnetically conductive element 21 has a first surface 21a, a second surface 21b opposite to the first surface 21a, an outer side surface 21c adjacent to and connecting the first surface 21a and the second surface 21b, and a through hole 210 communicating the first surface 21a and the second surface 21b. Therefore, the magnetically conductive element 21 has a ring shape. The wall surface of the through hole 210 constitutes an inner side surface 21d of the magnetically conductive element 21.

The conductor structure 22 is formed on the first surface 21a, the second surface 21b and the outer side surface 21c of the magnetically conductive element 21 and extends into the through hole 210 so as to cause the conductor structure 22 and the magnetically conductive element 21 to generate a magnetic flux and cause the conductor structure 22 and the magnetically conductive element 21 to constitute an inductor.

The base body 20 has a substrate 200 and an encapsulant 201. The magnetically conductive element 21 and the conductor structure 22 are positioned on the substrate 200 and encapsulated by the encapsulant 201. In particular, the substrate 200 is a ceramic substrate, a metal plate, a copper foil substrate, a circuit board, a wafer, a chip or a package. The encapsulant 201 is made of a molding compound and formed by molding. Further, the encapsulant 201 is filled in the through hole 210. In addition, the substrate 200 can have internal circuits (not shown) and a plurality of conductive vias (not shown) formed in dielectric layers of the substrate 200 for electrically connecting the internal circuits.

Further, an electronic element can be disposed on the substrate 200 of the base body 20. The electronic element can be an active element such as a semiconductor chip, a passive element such as a resistor, a capacitor or an inductor, or a combination thereof.

In the present embodiment, the conductor structure 22 has a circuit layer 220 formed on the first surface 21a of the magnetically conductive element 21 and a plurality of conductive wires 221 formed over the second surface 21b of the magnetically conductive element 21. Each of the conductive wires 221 has two opposite ends 221a, 221b electrically connected to the circuit layer 220 in a manner that the conductor structure 22 is formed with a plurality of coils connected in series and positioned around the ring-shaped magnetically conductive element 21.

In particular, the conductive wires 221 are bonding wires such as gold wires and formed by a wire bonding process. The circuit layer 220 is made of copper. By performing a sputtering, coating or electroplating process, the circuit layer 220 is formed on the dielectric layer of the substrate 200 and electrically connected to the internal circuits and the conductive vias of the substrate 200.

In the present embodiment, two conductive wires 221 are provided at a single wire bonding position. In other embodiments, one or more than two conductive wires can be provided at a single wire bonding position.

Further, the circuit layer 220 has a plurality of conductive traces 220a, 220b. The two opposite ends 221a, 22b of each of the conductive wires 221 are electrically connected to different two of the conductive traces 220a, 220b, respectively.

In addition, the conductive wires 221 extend from the circuit layer 220 at an outer periphery of the outer side surface 21c of the magnetically conductive element 21, over the second surface 21b of the magnetically conductive element 21, to the circuit layer 220 in the through hole 210.

In other embodiments, the base body 20 can be a dielectric layer (not shown) made of a dielectric material. The dielectric material is filled in the through hole 210 to embed the magnetically conductive element 21 in the dielectric layer, and the circuit layer 220 is formed in the dielectric layer.

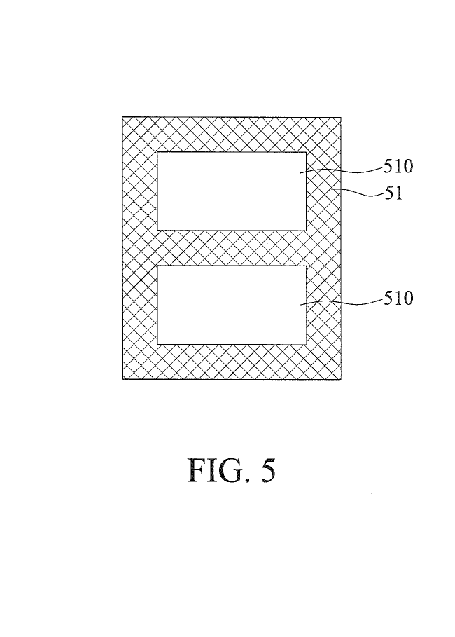

FIG. 3 is a schematic cross-sectional view of an electronic device 3 according to a second embodiment of the present invention. The second embodiment differs from the first embodiment in the configuration of the conductor structure 32.

Referring to FIG. 3, the conductor structure 32 further has a plurality of bonding pads 320 formed on the second surface 21b of the magnetically conductive element 21. Each of the conductive wires 321 has a first segment 321a and a second segment 321b bonded to a corresponding one of the bonding pads 320. In particular, the first segment 321a extends in the through hole 210 of the magnetically conductive element 21 for connecting the circuit layer 220 and the bonding pad 320, and the second segment 321b extends over the outer side surface 21c of the magnetically conductive element 21 for connecting the circuit layer 220 and the bonding pad 320.

In the present embodiment, the bonding pads 320 are made of copper and formed by a routing process.

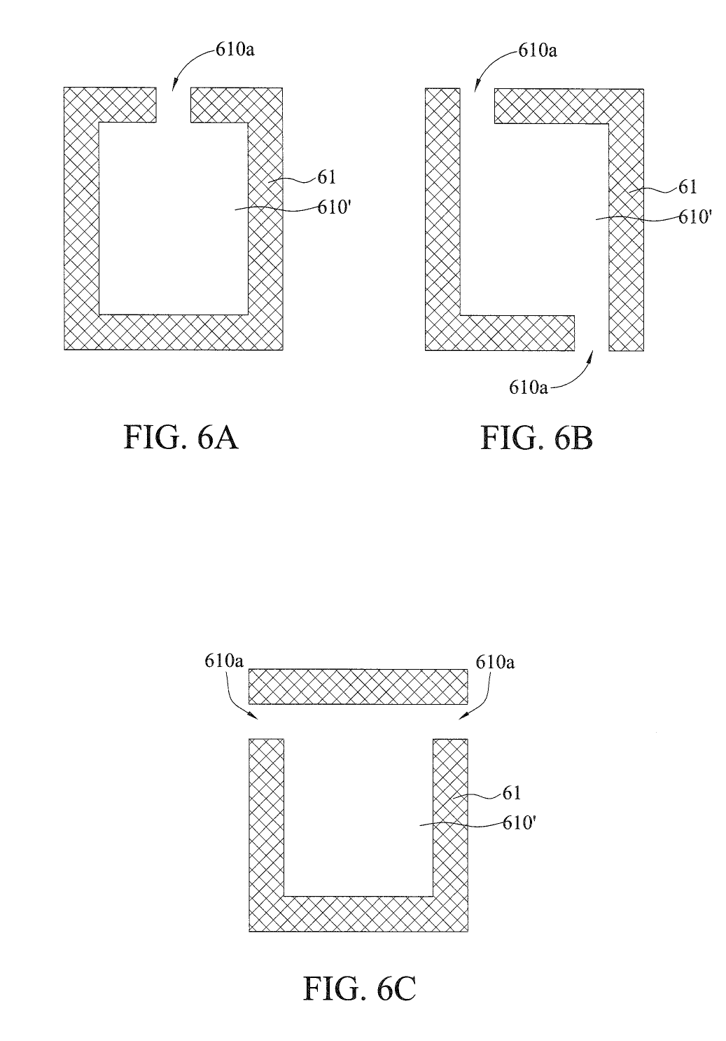

FIGS. 4A to 4C are schematic cross-sectional views of electronic devices 4, 4′, 4″ according to a third embodiment of the present invention. The third embodiment differs from the first embodiment in the configuration of the conductor structures 42, 42′, 42″.

Referring to FIG. 4A, the conductor structure 42 further has a plurality of conductive posts 420 formed on the circuit layer 220 in the through hole 210 of the magnetically conductive element 21, and one ends 221a of the conductive wires 221 are bonded to the conductive posts 420.

Referring to FIG. 4B, the conductor structure 42′ further has a plurality of conductive posts 420′ formed on the circuit layer 220 at an outer periphery of the outer side surface 21c of the magnetically conductive element 21, and one ends 221b of the conductive wires 221 are bonded to the conductive posts 420′.

Referring to FIG. 4C, the conductor structure 42″ further has a plurality of conductive posts 420″ formed on the circuit layer 220 in the through hole 210 and at an outer periphery of the outer side surface 21c of the magnetically conductive element 21. One ends of the conductive wires 221 are bonded to the conductive posts 420″ formed on the circuit layer 220 in the through hole 210 and the other ends of the conductive wires 221 are bonded to the conductive posts 420″ formed at the outer periphery of the outer side surface 21c of the magnetically conductive element 21.

In the present embodiment, the conductive posts 420, 420′, 420″ are made of copper and formed by a routing process.

In the electronic device 2, 3, 4, 4′, 4″, the magnetically conductive element 21 is provided with a through hole 210 to allow the conductor structure 22, 32, 42, 42′, 42″ to be formed around the magnetically conductive element 21. As such, the magnetic field tends to focus on a ferromagnetic path of low magnetic reluctance, thereby increasing the magnetic flux and resulting in an increase in inductance. The inductance value of the present invention can be increased to 75 nH, which is far greater than the conventional inductance value of 17 nH.

Further, since the magnetically conductive element 21 having the through hole 210 facilitates to increase the inductance value of a single coil, the present invention can achieve the same inductance value as the prior art by using a reduced number of coils. For example, compared with the conventional coil-type inductor that needs three coils to achieve an inductance value of 17 nH, the present invention only needs one coil to achieve the inductance value of 17 nH.

By reducing the number of coils, the present invention reduces the volume of the inductor constituted by the conductor structure 22, 32, 42, 42′, 42″ and the magnetically conductive element 21. Further, since the magnetically conductive element 21 has no circuit formed therein, the volume of the magnetically conductive element 21 can be reduced according to the practical need. Therefore, the inductor of the present invention meets the miniaturization requirement.

Compared with the prior art, the electronic device 2, 3, 4, 4′, 4″ of the present invention occupies less space and achieves a larger inductance value.

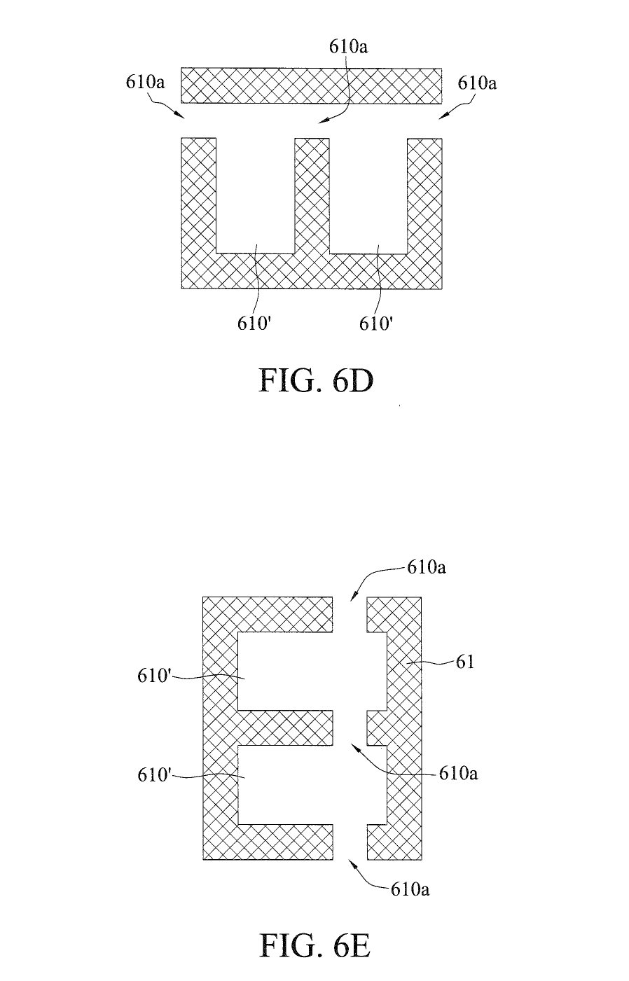

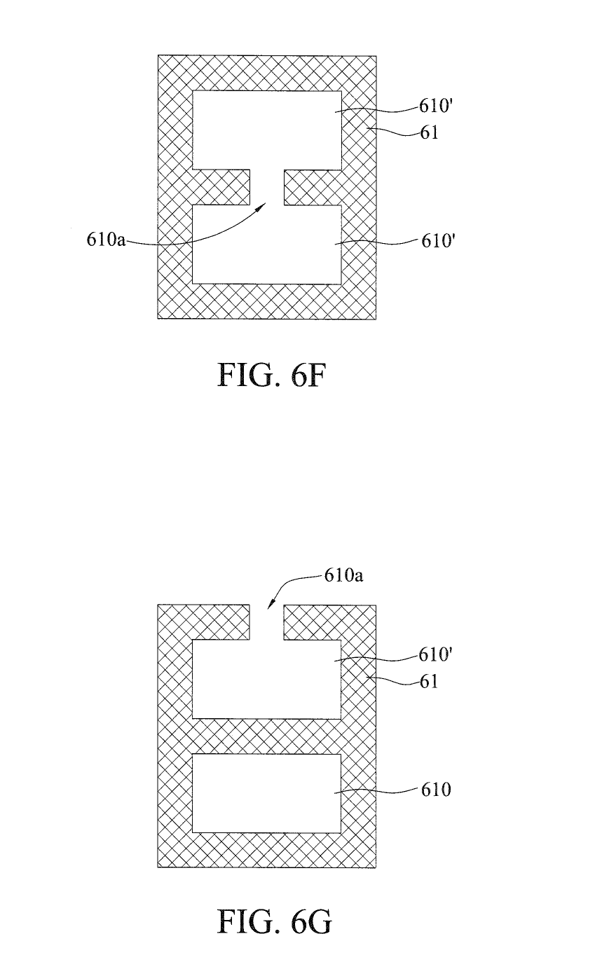

FIG. 5 and FIGS. 6A to 6G are schematic upper views of electronic devices according to fourth and fifth embodiments of the present invention. The fourth and fifth embodiments differ from the first embodiment in the configuration of the magnetically conductive element.

Referring to FIG. 5, the magnetically conductive element 51 has a plurality of through holes 510. In the present embodiment, the magnetically conductive element 51 has two through holes and has a “ [symbol] ” shape in upper view. In other embodiments, the magnetically conductive element 51 can have more through holes and have such as a “ [symbol] ” shape in upper view.

Referring to FIGS. 6A to 6G different from the closed through hole 210 of the magnetically conductive element 21 of the first embodiment, the magnetically conductive element 61 of the fifth embodiment has one or more open through holes 610′. For example, referring to FIG. 6A, the magnetically conductive element 61 has one open through hole 610′ having one opening 610a. Referring to FIGS. 6B and 6C, the magnetically conductive element 61 has one open through hole 610′ having a plurality of openings 610a. Referring to FIGS. 6D and 6E, the magnetically conductive element 61 has a plurality of open through holes 610′ each having a plurality of openings 610a. Referring to FIG. 6F, the magnetically conductive element 61 has two open through holes 610′ having a common opening 610a. Referring to FIG. 6G the magnetically conductive element 61 has a closed through hole 610 and an open through hole 610′ having an opening 610a.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. An electronic device, comprising:
a magnetically conductive element having a first surface, a second surface opposite to the first surface, an outer side surface adjacent to and connecting the first surface and the second surface, and at least a through hole communicating the first surface and the second surface;
a conductor structure formed on the first surface, the second surface and the outer side surface of the magnetically conductive element and extending into the through hole for generating a magnetic flux; and
a base body encapsulating the magnetically conductive element and the conductor structure.

2. The device of claim 1, wherein the base body comprises a substrate and an encapsulant, the magnetically conductive element and the conductor structure being positioned on the substrate and encapsulated by the encapsulant.

3. The device of claim 2, wherein the substrate is a ceramic substrate, a metal plate, a copper foil substrate, a circuit board, a wafer, a chip or a package.

4. The device of claim 1, wherein the magnetically conductive element is made of ferrite, Fe, Mn, Zn, Ni or an alloy thereof.

5. The device of claim 1, wherein the conductor structure comprises a circuit layer formed on the first surface of the magnetically conductive element and a plurality of conductive wires formed over the second surface of the magnetically conductive element, each of the conductive wires having two opposite ends electrically connected to the circuit layer.

6. The device of claim 5, wherein the circuit layer has a plurality of conductive traces, the two opposite ends of each of the conductive wires being electrically connected to different two of the conductive traces, respectively.

7. The device of claim 5, wherein the conductor structure further comprises a plurality of bonding pads formed on the second surface of the magnetically conductive element, and each of the conductive wires has two segments bonded to a corresponding one of the bonding pads, one of the segments extending in the through hole of the magnetically conductive element for connecting the circuit layer and the bonding pad and the other segment extending over the outer side surface of the magnetically conductive element for connecting the circuit layer and the bonding pad.

8. The device of claim 5, wherein the conductor structure further comprises a plurality of conductive posts formed on the circuit layer in the through hole of the magnetically conductive element, one ends of the conductive wires being bonded to the conductive posts.

9. The device of claim 5, wherein the conductor structure further comprises a plurality of conductive posts formed on the circuit layer at an outer periphery of the outer side surface of the magnetically conductive element, one ends of the conductive wires being bonded to the conductive posts.

10. The device of claim 9, wherein the conductor structure further comprises a plurality of conductive posts formed on the circuit layer in the through hole of the magnetically conductive element, the other ends of the conductive wires being bonded to the conductive posts in the through hole.

11. The device of claim 1, wherein the through hole is a closed through hole.

12. The device of claim 1, wherein the through hole is an open through hole.

13. The device of claim 12, wherein the open through hole has at least an opening.
